(19) United States
(12) Patent Application Publication
(10) Pub. No.: US 2018/0151760 A1
(43) Pub. Date: May 31, 2018

(54) PHOTOELECTRIC CONVERSION DEVICE, DRIVE METHOD OF PHOTOELECTRIC CONVERSION DEVICE, AND IMAGING SYSTEM

(71) Applicant: CANON KABUSHIKI KAISHA, Tokyo (JP)

(72) Inventor: Kazuaki Tashiro, Isehara-shi (JP)

(21) Appl. No.: 15/815,125

(22) Filed: Nov. 16, 2017

(30) Foreign Application Priority Data
Nov. 30, 2016 (JP) 2016-232378

(51) Int. Cl. H01L 31/0224; H01L 51/42; H01L 51/44; H01L 31/04

(52) U.S. Cl. CPC H01L 31/022425; H01L 31/04; H01L 51/441; H01L 51/42

(57) ABSTRACT

A photoelectric conversion device includes: a first electrode; a second electrode; a photoelectric conversion layer arranged between the first electrode and the second electrode; a floating gate electrode connected to the second electrode and adapted to accumulate signal charges generated in the photoelectric conversion layer; an amplification transistor adapted to output a signal corresponding to a potential of the floating gate electrode; and a charge injection portion arranged between the first electrode and the photoelectric conversion layer and adapted to inject opposite polarity charges of signal charges from the first electrode to the photoelectric conversion layer to reset signal charges accumulated in the floating gate electrode.

### BACKGROUND OF THE INVENTION

### Field of the Invention

The present invention relates to a photoelectric conversion device, a drive method of the photoelectric conversion device, and an imaging system.

### Description of the Related Art

As a photoelectric conversion device used for an image sensor or the like of a camera, stacked photoelectric conversion devices have been proposed. In a photoelectric conversion device disclosed in FIG. 2 of Japanese Patent Application Laid-Open No. 2011-187544, a photoelectric conversion film is stacked on a semiconductor substrate. A transparent electrode is arranged on the photoelectric conversion film, and a pixel electrode is arranged under the photoelectric conversion film. In the photoelectric conversion device of Japanese Patent Application Laid-Open No. 2011-187544, the pixel electrode is connected to only the gate electrode of an amplification transistor to suppress occurrence of a dark current from the substrate. Readout of a pixel signal is performed from the pixel electrode side, and reset operation is performed by draining signal charges from the transparent electrode side.

The device disclosed in Japanese Patent Application Laid-Open No. 2011-187544 performs a reset operation by draining charges accumulated in the pixel electrode to a common electrode side via a photoelectric conversion layer. At this time, it is necessary to inject signal charges to the photoelectric conversion layer from the pixel electrode. In Japanese Patent Application Laid-Open No. 2011-187544, however, since the amount of injection is suppressed due to an energy barrier of the pixel electrode and the photoelectric conversion layer, time is required to drain signal charges and thus there is a problem of delay in the reset operation.

In view of the above problem, the present invention intends to provide a photoelectric conversion device that can perform a fast reset operation while suppressing a noise.

### SUMMARY OF THE INVENTION

A photoelectric conversion device of an embodiment according to one aspect of the present invention includes: a first electrode; a second electrode; a photoelectric conversion layer arranged between the first electrode and the second electrode; a floating gate electrode connected to the second electrode and adapted to accumulate signal charges generated in the photoelectric conversion layer; an amplification transistor adapted to output a signal corresponding to a potential of the floating gate electrode; and a charge injection portion arranged between the first electrode and the photoelectric conversion layer and adapted to inject opposite polarity charges of signal charges from the first electrode to the photoelectric conversion layer to reset signal charges accumulated in the floating gate electrode.

A drive method of a photoelectric conversion device of an embodiment according to another aspect the present invention is a drive method of a photoelectric conversion device having a first electrode, a second electrode, a photoelectric conversion layer arranged between the first electrode and the second electrode, a floating gate electrode connected to the second electrode and adapted to accumulate signal charges generated in the photoelectric conversion layer, an amplification transistor adapted to output a signal corresponding to a potential of the floating gate electrode, and a charge injection portion arranged between the first electrode and the photoelectric conversion layer, and the drive method includes: injecting opposite polarity charges of signal charges from the first electrode to the photoelectric conversion layer to reset signal charges accumulated in the floating gate electrode.

Further features of the present invention will become apparent from the following description of exemplary embodiments with reference to the attached drawings.

### BRIEF DESCRIPTION OF THE DRAWINGS

FIG. 1A and FIG. 1B are diagrams schematically illustrating a pixel of a photoelectric conversion device in a first embodiment of the present invention.

FIG. 2 is a circuit block diagram of the photoelectric conversion device in the first embodiment.

FIG. 3 is an equivalent circuit of a column amplification circuit in the first embodiment.

FIG. 4 is a diagram schematically illustrating the planer structure of a pixel of the photoelectric conversion device in the first embodiment.

FIG. 5 is a diagram schematically illustrating the sectional structure of the photoelectric conversion device in the first embodiment.

FIG. 6A and FIG. 6B are diagrams illustrating I-V characteristics of a diode of the photoelectric conversion unit in the first embodiment.

FIG. 7A and FIG. 7B are diagrams schematically illustrating a potential of the photoelectric conversion unit in the first embodiment.

FIG. 8A and FIG. 8B are diagrams schematically illustrating a potential of a modified example of the photoelectric conversion unit in the first embodiment.

FIG. 9 is a diagram illustrating a timing chart of the photoelectric conversion device in the first embodiment.

FIG. 10 is a diagram schematically illustrating the structure of a pixel of a photoelectric conversion device in a second embodiment.

FIG. 11 is a circuit block diagram of the photoelectric conversion device in the second embodiment.

FIG. 12 a diagram schematically illustrating the planer structure of a pixel of the photoelectric conversion device in the second embodiment.

FIG. 13 is a diagram schematically illustrating the sectional structure of the photoelectric conversion device in the second embodiment.

FIG. 14A and FIG. 14B are diagrams schematically illustrating a potential of a photoelectric conversion unit in a third embodiment.

FIG. 15 is a block diagram of a photoelectric conversion system in a fourth embodiment.

FIG. 16A and FIG. 16B are block diagrams of an imaging system related to an on-vehicle camera in a fifth embodiment.

### DESCRIPTION OF THE EMBODIMENTS

Preferred embodiments of the present invention will now be described in detail in accordance with the accompanying drawings.

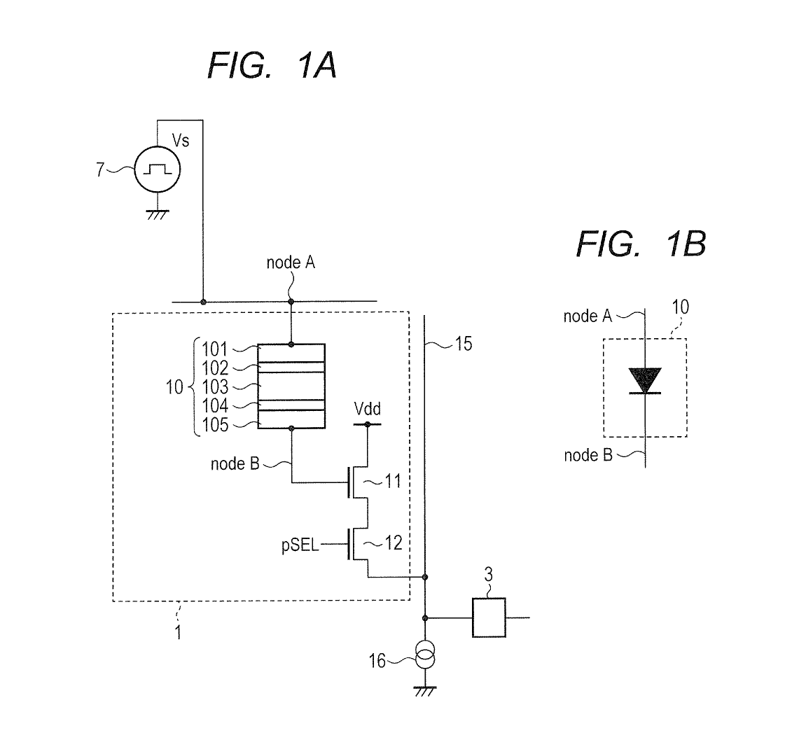

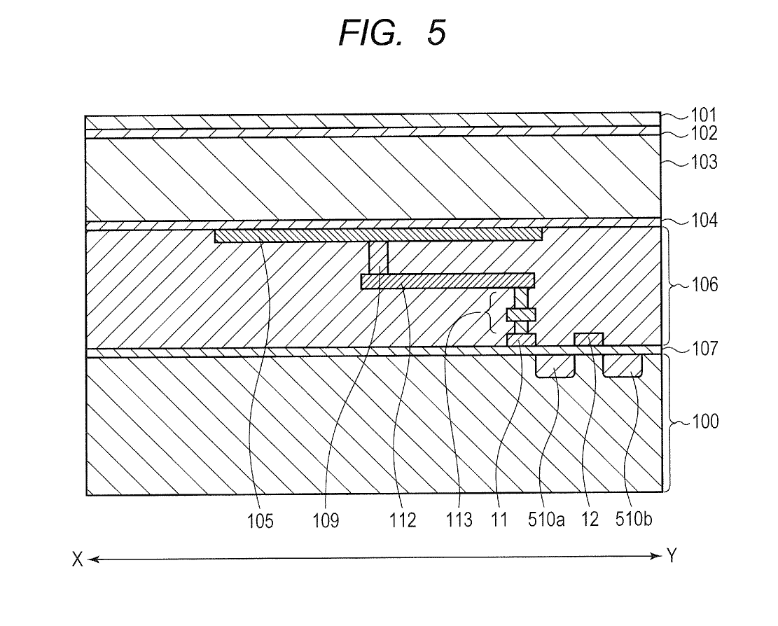

A photoelectric conversion device in one embodiment of the present invention includes a semiconductor substrate, a first electrode, a second electrode, a photoelectric conversion layer arranged between the first electrode and the second electrode, and a floating gate electrode connected to the second electrode. The photoelectric conversion layer is configured to photoelectrically convert a light entering the photoelectric conversion layer into charges. Note that not the entire photoelectric conversion layer is required to have a function of photoelectric conversion. A circuit unit that receives a signal which is based on signal charges generated by photoelectric conversion is arranged in the semiconductor substrate. In some embodiments, the photoelectric conversion device includes a plurality of pixels. In these embodiments, a plurality of circuit units are arranged correspondingly to the plurality of pixels. Each of the plurality of circuit units may include an amplification unit that amplifies a signal. FIG. 5 illustrates a semiconductor substrate 100 and a photoelectric conversion layer 103 as an example. Further, FIG. 1A illustrates an equivalent circuit of a pixel 1 as an example of the circuit unit.

In FIG. 5, a first electrode (common electrode) 101 is arranged on the semiconductor substrate 100. A second electrode (pixel electrode) 105 is arranged between the first electrode 101 and the semiconductor substrate 100. A first blocking layer (opposite polarity charge injection portion) 102, the photoelectric conversion layer 103, and a second blocking layer 104 are arranged between the first electrode 101 and the second electrode 105. Although the first blocking layer 102 is provided in this example, a blocking function may be realized by junction of the first electrode 101 and the photoelectric conversion layer 103. Also for the second blocking layer 104, a function of blocking signal charges and a function of injecting opposite polarity charges of signal charges may be realized by junction of the photoelectric conversion layer 103 and the second electrode 105. The function of blocking signal charges is used at photoelectric conversion, and the function of injecting opposite polarity charges of signal charges is used at reset. The blocking layer may be formed of a semiconductor material. The semiconductor material may be selected from an inorganic semiconductor material such as silicon, germanium, gallium arsenide and an organic semiconductor material. The semiconductor material forming the photoelectric conversion layer and the semiconductor material forming the blocking layer may be different from each other. Alternatively, the bandgap of the semiconductor material forming an accumulation layer and the bandgap of the semiconductor material forming the blocking layer may be different from each other. A bandgap is the difference between a lowest energy level of a conduction band and a highest energy level of a valence band. The material forming the blocking layer is not limited to a semiconductor material.

A photoelectric conversion layer formed of a single layer may include a first portion and a second portion which have different characteristics from each other. Such a configuration allows the first portion and the second portion to function as the photoelectric conversion layer and the blocking layer, respectively. For example, when the photoelectric conversion layer is formed of a semiconductor material, the impurity concentration of the first portion and the impurity concentration of the second portion in the semiconductor material may be different from each other.

Further, the function of blocking signal charges and the function of injecting opposite polarity charges of the signal charges may be realized at a junction interface between the photoelectric conversion layer and the electrode as described above.

Embodiments of the present invention will be described below in detail by using the drawings. The present invention is not limited to only the embodiments described below. Modified examples in which some configuration of the embodiments described below is changed without departing from the spirit of the present invention are also considered to be an embodiment of the present invention. Further, examples in which some configuration of any of the embodiments described below is added to another embodiment or replaced with some configuration of another embodiment are also considered to be an embodiment of the present invention.

### First Embodiment

Pixel Configuration

FIG. 1A schematically illustrates a pixel 1 of a photoelectric conversion device in the present embodiment, and FIG. 1B illustrates an equivalent circuit of a photoelectric conversion unit 10. The pixel 1 includes the photoelectric conversion unit 10, an amplification transistor 11, and a selection transistor 12. The amplification transistor 11 and the selection transistor 12 are each formed of a Metal Oxide Semiconductor (MOS) transistor and form a circuit unit that receives a signal based on signal charges generated by photoelectric conversion. The photoelectric conversion unit 10 includes a first electrode 101, a first blocking layer (opposite polarity charge injection portion) 102, a photoelectric conversion layer 103, a second blocking layer 104, and a second electrode 105.

The photoelectric conversion unit 10 forms a photodiode having a first terminal connected to a node A and a second terminal connected to a node B. The node A is connected to a voltage control unit 7. The voltage control unit 7 controls a bias voltage Vs applied to the first terminal of the photoelectric conversion unit 10 via a row drive circuit 2. Such a configuration enables reset, accumulation, and readout of charges at the photoelectric conversion unit 10.

The node B is connected to the gate of the amplification transistor 11. The gate of the amplification transistor 11 is an input node of an amplification unit. Such a configuration allows the amplification unit to amplify a pixel signal from the photoelectric conversion unit 10. That is, in the present embodiment, the circuit unit that receives a pixel signal which is based on charges generated by photoelectric conversion includes the amplification unit.

The amplification transistor 11 operates as a source follower and outputs a pixel signal which is based on charges generated in the photoelectric conversion unit 10. The node B of the photoelectric conversion unit 10 is connected to the gate of the amplification transistor 11. The gate of the amplification transistor 11 is the input node of the amplification unit and accumulates charges as a floating gate electrode. The drain of the amplification transistor 11 is connected to the power source voltage line Vdd, and the source is electrically connected to a column signal line 15 via the selection transistor 12. A drive signal pSEL is applied to the gate of the selection transistor 12 and, when the selection transistor 12 is turned on, a pixel signal based on charges of the photoelectric conversion unit 10 is output to the column signal line 15.

The pixel 1 of the present embodiment has no reset transistor for resetting the node B. The node B is a floating gate electrode. Here, a floating gate electrode is an electrode in which a gate electrode is not electrically connected to a semiconductor substrate. In general, when reset is made by a reset transistor, a reset noise (kTC noise) may occur. Thus, in the present embodiment, reset of the node B is performed by a film reset operation of a photoelectric conversion layer described later.

Configuration of Imaging Device

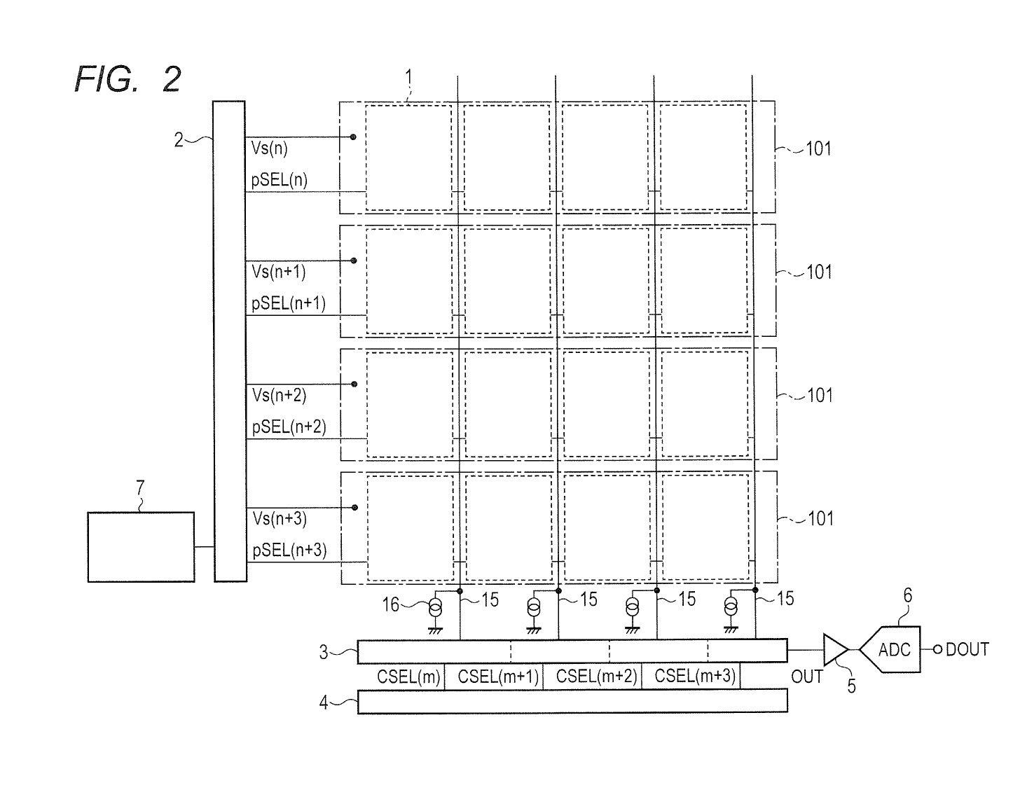

FIG. 2 is a circuit block diagram of the photoelectric conversion device of the present embodiment. The portions having the same function as those in FIG. 1A are labeled with the same reference numeral. The photoelectric conversion device includes a plurality of pixels 1, a row drive circuit 2, a column circuit 3, a column drive circuit 4, an output circuit 5, an analog-to-digital conversion circuit (ADC) 6, and a voltage control unit 7. The plurality of pixels 1 form a pixel array arranged in a two-dimensional matrix in the row direction and the column direction.

While FIG. 2 depicts 16 pixels 1 arranged in a matrix of four rows by four columns, the number of the pixels is not limited thereto. Note that, in the present specification, the row direction refers to the horizontal direction in the drawings, and the column direction refers to the vertical direction in the drawings. Micro lenses and color filters may be arranged on the pixels 1. The color filters are primary color filters of red, blue, and green, for example, and are provided on respective pixels 1 according to the Bayer arrangement. Some of the pixels 1 are shielded from a light as optical black pixels (OB pixel). When utilized in a fifth embodiment described later, the plurality of pixels 1 may be provided with a ranging row on which focus detection pixels that output pixel signals used for focus detection are arranged and a plurality of image pickup rows on which image pickup pixels that output pixel signals for generating an image are arranged. The plurality of pixels 1 included in one column are connected to one column signal line 15.

The row drive circuit 2 applies a bias voltage Vs(n) to the first electrode 101 on the n-th row and applies a drive signal pSEL(n) to the gate of the selection transistor 12. The plurality of pixels 1 included in one row are connected to a common drive signal line. The drive signal line is a wiring that transfers the drive signal pSEL or the like. Note that, in FIG. 2, in order to distinguish drive signals supplied to different rows, references such as (n), (n+1), and the like denoting rows are provided. The row drive circuit 2 supplies the bias voltage Vs(n) and the drive signal pSEL(n) to the pixels 1 on each row via the drive signal lines to perform readout scan of the pixels 1 on a row basis. That is, the drive signal pSEL(n) controls accumulation and reset of charges in the photoelectric conversion unit 10 and controls transfer of a pixel signal from the pixel 1 to the column signal line 15. The row drive circuit 2 is controlled by a timing generator (not illustrated). The voltage control unit 7 is formed of a constant voltage circuit, a buffer circuit, a digital-to-analog conversion circuit, and the like and generates and supplies a plurality of different bias voltages Vs to the row drive circuit 2.

The first electrode 101 forms the first terminal (the node A of FIG. 1A) of the photoelectric conversion unit 10. In the plurality of pixels 1 included in one row, the first terminals of the photoelectric conversion units 10 are formed of the common first electrode 101. In the present embodiment, the first electrodes 101 are arranged for each row. The row drive circuit 2 selects a row to which the bias voltage Vs is supplied from the voltage control unit 7. Note that, in order to distinguish the bias voltages Vs supplied to the different rows, references such as (n), (n+1), and the like denoting rows are provided.

The column circuit 3 includes column amplification circuits 30 for respective columns, and the column amplification circuits 30 are connected to the respective column signal lines 15. The column drive circuit 4 drives the column circuit 3 on a column basis. A current source 16, which is a load of the amplification transistor 11 of the pixel 1, is connected to each of the column signal lines 15. The column amplification circuit 30 amplifies and holds a pixel signal output to the column signal line 15. The column drive circuit 4 is formed of a shift resistor or the like and supplies a drive signal CSEL(m) to the column amplification circuit 30 on the m-th column. Note that, in order to distinguish drive signals supplied to different columns, references such as (m), (m+1), and the like denoting rows are provided. The output circuit 5 is formed of a clamping circuit, a differential amplification circuit, a buffer circuit, and the like and outputs a pixel signal to the analog-to-digital conversion circuit 6. The analog-to-digital conversion circuit 6 is formed of a ramp signal generation circuit, a differential amplification circuit, and the like, converts an input pixel signal into digital data, and outputs the digital data from the output terminal DOUT. With such a configuration, pixel signals read out in parallel on a row basis can be sequentially output.

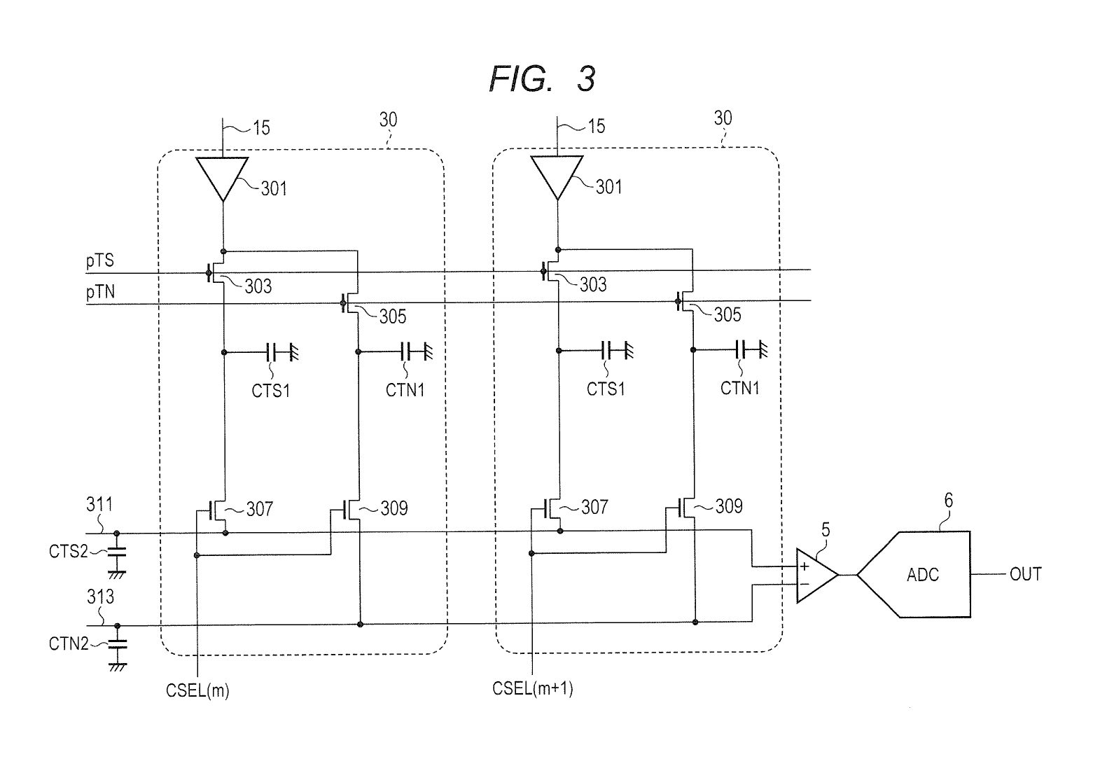

FIG. 3 illustrates an equivalent circuit of the column amplification circuits 30 in the present embodiment and, in particular, illustrates the column amplification circuits 30 on the m-th column and (m+1)-th column. While not depicted, other column amplification circuits 30 of the column circuit 3 have the same configuration. Each of the column amplification circuits 30 has an amplifier 301, sample and hold (S/H) switches 303 and 305, horizontal transfer switches 307 and 309, and capacitors CTS1 and CTN1. The input node of the amplifier 301 is connected with the column signal line 15, and the amplifier 301 amplifies a pixel single input from the column single line 15. The output node of the amplifier 301 is connected to the capacitor CTS1 via the S/H switch 303. Further, the output node of the amplifier 301 is connected to the capacitor CTN1 via the S/H switch 305. The S/H switches 303 and 305 are controlled by drive signals pTS and pTN, respectively. In response to the S/H switch 305 being turned on, a pixel signal N including a threshold variation of the amplification transistor 11 from the pixel 1 is held in the capacitor CTN1. Further, in response to the S/H switch 303 being turned on, a pixel signal S including an optical signal and a threshold variation of the amplification transistor 11 is held in the capacitor CTS1.

The capacitor CTS1 is connected to a horizontal output line 311 via the horizontal transfer switch 307. The capacitor CTN1 is connected to a horizontal output line 313 via the horizontal transfer switch 309. The horizontal transfer switches 307 and 309 are controlled by a drive signal CSEL from the column drive circuit 4. In response to the horizontal transfer switch 307 being turned on, the pixel signal S is output from the capacitor CTS1 to the horizontal output line 311 and held in a capacitor CTS2. In response to the horizontal transfer switch 309 being turned on, the pixel signal N is output from the capacitor CTN1 to the horizontal output line 313 and held in a capacitor CTN2.

The horizontal output line 311 and the horizontal output line 313 are connected to the output circuit 5. The output circuit 5 outputs the difference between the pixel signal S of the horizontal output line 311 and the pixel signal N of the horizontal output line 313 to the analog-to-digital conversion circuit 6. A use of the difference between the pixel signal S and the pixel signal N allows for removal of the threshold variation of the amplification transistor 11. The analog-to-digital conversion circuit 6 converts an input analog signal to a digital signal.

Note that the column amplification circuit 30 may include an analog-to-digital conversion circuit. In this case, the analog-to-digital conversion circuit has a holding unit such as a memory, a counter, or the like that holds a digital signal. The pixel signal S and the pixel signal N are converted into digital signals, respectively, and held in the holding unit. By calculating the difference between the pixel signal S and the pixel signal N converted into digital signals, a pixel signal in which a noise component such as a threshold variation is removed can be obtained.

Planer Structure and Sectional Structure of Photoelectric Conversion Device

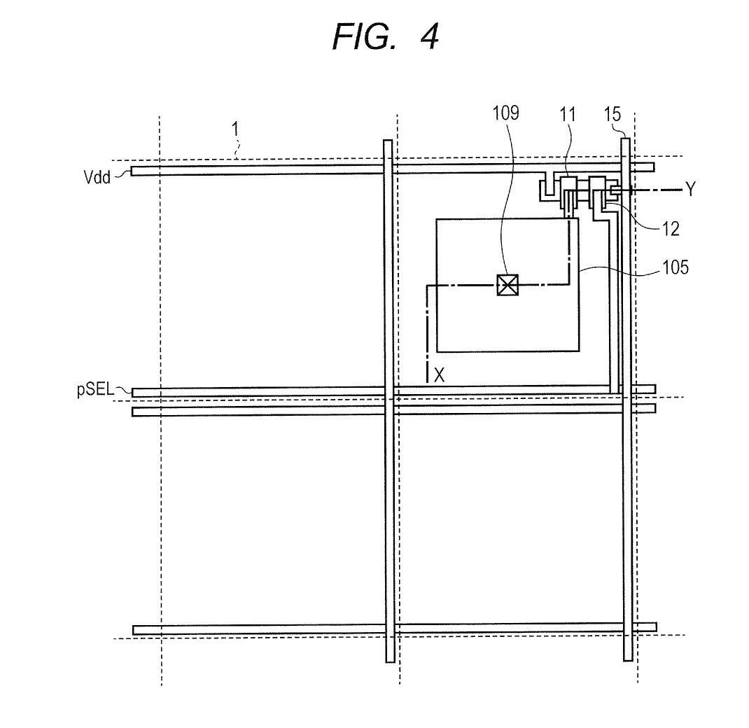

Next, the planer structure and the sectional structure of the photoelectric conversion device of the present embodiment will be described. FIG. 4 schematically illustrates the planer structure of four pixels 1 arranged in a matrix of two rows by two columns. While the planer structure is depicted for one of the four pixels 1, other pixels have the same configuration. FIG. 5 schematically illustrates the sectional structure of the photoelectric conversion device taken along an X-Y dot-dash line of FIG. 4. Note that portions having the same function as those in FIG. 1A and FIG. 2 are labeled with the same reference. For the transistors, references are provided to the corresponding gate electrodes.

In FIG. 4, the second electrode 105 is arranged in the middle of the pixel 1, and the amplification transistor 11 and the selection transistor 12 are arranged at the corner of the pixel 1. The power source voltage line Vdd is connected to the drain region of the amplification transistor 11, the source region of the selection transistor 12 is connected to the column signal line 15. The arrangement and the shape of the second electrode 105, the amplification transistor 11, and the selection transistor 12 are not limited to those depicted in FIG. 4, and various configuration may be employed.

In FIG. 5, the semiconductor substrate 100 is formed of a silicon substrate of a first conduction type (for example, P-type), impurity semiconductor regions (impurity diffusion portions) 510a and 510b of a second conduction type (for example, N-type) are arranged in the semiconductor substrate 100. The impurity semiconductor region 510a forms a source region of the amplification transistor 11 and the drain region of the selection transistor 12. Further, the impurity semiconductor region 510b forms a source region of the selection transistor 12. A gate insulating film 107 made of, for example, a silicon oxide film is formed on the semiconductor substrate 100. The gate electrode of the amplification transistor 11 and the gate electrode of the selection transistor 12 are formed on the gate insulating film 107. Further, a wiring layer 106 containing a conductive member such as aluminum, copper, polysilicon, or the like is formed on the gate insulating film 107. The gate electrode of the amplification transistor 11 is electrically connected to the second electrode 105 via a conductive member 112 and a contact plug 109.

The second electrode (pixel electrode) 105 and the gate electrode of the amplification transistor 11 form the node B that is connected by only the contact plug 109, the conductive member 112, and the contact plug 113. The node B forms the floating gate electrode. Since the node B is not electrically conducted to the impurity semiconductor region (impurity diffusion portion) 510a, no dark current due to the semiconductor substrate 100 occurs.

A second blocking layer 104, a photoelectric conversion layer 103, a first blocking layer 102, and a first electrode 101 are formed in this order on the second electrode 105. The photoelectric conversion layer 103 is arranged between the first electrode 101 and the second electrode 105, and the first blocking layer 102 is arranged between the first electrode 101 and the photoelectric conversion layer 103. The second blocking layer 104 is arranged between the photoelectric conversion layer 103 and the second electrode 105. The first electrode 101, the first blocking layer 102, the photoelectric conversion layer 103, the second blocking layer 104, and the second electrode 105 form the photoelectric conversion unit 10. When a reverse bias is applied to the photoelectric conversion unit 10, the first blocking layer 102 has a function of blocking (preventing) electrons, which are signal charges, from being injected from the first electrode 101 to the photoelectric conversion layer 103. On the other hand, when a forward bias is applied to the photoelectric conversion unit 10, the first blocking layer 102 functions as a charge injection portion that quickly injects halls that are charges with a polarity opposite to electrons, which are signal charges, from the first electrode to the photoelectric conversion layer 103.

While being electrically insulated on a row basis, the first electrodes 101 are formed of a shared conductive member in the plurality of pixels 1 included in one row. Thus, in the following description, the first electrode 101 may be called a common electrode. Further, the second electrode 105 of each of the pixels 1 is electrically insulated from the second electrode 105 of another pixel 1. That is, the second electrodes 105 are provided in a separate manner to the plurality of pixels, respectively. Thus, in the following description, the second electrode 105 may be called a pixel electrode.

The first electrode 101 may be formed of a conductive member having a high optical transparency, for example, a compound such as Indium Tin Oxide (ITO) containing indium or tin, a compound such as ZnO, or the like. Such a configuration allows more light to enter the photoelectric conversion layer 103, which can improve the sensitivity of the photoelectric conversion unit 10. Note that a thinned polysilicon or a thinned metal that can transmit a light may be used as the first electrode 101. When a metal is used for the first electrode 101, further reduction in power consumption and increase in speed can be realized because of a low electrical resistance of the metal.

For the first blocking layer 102, a semiconductor which is homogeneous to the semiconductor used for the photoelectric conversion layer 103 and is an N-type or a P-type semiconductor whose impurity concentration is higher than the impurity concentration of the photoelectric conversion layer 103 can be used. For example, when an amorphous silicon (hereafter, referred to as “a-Si”) is used for the photoelectric conversion layer 103, an N-type or P-type a-Si whose impurity concentration is high is used for the first blocking layer 102. As described later, since the position of a Fermi level is different due to the difference of the impurity concentration, a potential barrier can be formed to only one of electrons or halls to prevent charges from being injected from the electrode. On the other hand, injection can be quickly performed on the opposite polarity charges.

Note that, when different materials (a first semiconductor material and a second semiconductor material) are used for the photoelectric conversion layer 103 and the first blocking layer 102, respectively, hetero junction is formed. Since the bandgap is different due to the difference in the material, a potential barrier can be formed to only one of electrons or halls, and injection can be quickly performed on the opposite polarity charges.

The photoelectric conversion layer 103 photoelectrically converts a light entering the photoelectric conversion layer 103 into charges. At least a part of the photoelectric conversion layer 103 may have a function of photoelectric conversion. The photoelectric conversion layer 103 may be formed of a semiconductor material such as an intrinsic a-Si, a low concentration P-type a-Si, a low concentration N-type a-Si, or the like. Alternatively, the photoelectric conversion layer 103 may be formed of a compound semiconductor material. For example, a III-V group compound semiconductor such as BN, GaAs, GaP, AlSb, GaAl, AsP, or the like, a II-VI group compound semiconductor such as CdSe, ZnS, HdTe, or the like, or a IV-VI group compound semiconductor such as PbS, PbTe, CuO, or the like may be employed. Alternatively, the photoelectric conversion layer 103 may be formed of an organic semiconductor material. For example, fullerene, coumarin 6 (C6), rhodamine 6G (R6G), zinc phthalocyanine (ZnPc), quinacridone, a phthalocyanine-based compound, a naphthalocyanine-based compound, or the like may be used. Furthermore, a layer including a quantum dot formed of the above-described semiconductor material may be used for the photoelectric conversion layer 103. It is desirable that the quantum dot be a particle whose particle diameter is 20.0 nm or less.

When the photoelectric conversion layer 103 is formed of a semiconductor material, it is preferable that the semiconductor material be doped with a lower concentration impurity or the semiconductor material be an intrinsic semiconductor. With such a configuration, since it is possible to sufficiently expand a depletion layer to the photoelectric conversion layer 103, the advantage of a higher sensitivity, a reduction of noise, or the like can be obtained.

The second blocking layer 104 is arranged at least between the photoelectric conversion layer 103 and the second electrode 105. For the second blocking layer 104, a semiconductor which is homogeneous to the semiconductor used for the photoelectric conversion layer 103 and is an N-type or a P-type semiconductor whose impurity concentration is higher than the impurity concentration of the photoelectric conversion layer 103 can be used. For example, when the a-Si is used for the photoelectric conversion layer 103, an N-type a-Si whose impurity concentration is high or a P-type a-Si whose impurity concentration is high is used for the first blocking layer 102. Since the position of a Fermi level is different due to the difference of the impurity concentration, a potential barrier can be formed to only one of electrons or halls to prevent charges from being injected from the electrode.

Note that the first blocking layer 102 may be formed of a different material from the photoelectric conversion layer 103 to cause hetero junction to be formed. Since the bandgap is different due to the difference in the material, a potential barrier can be formed to only one of electrons or halls. It is possible to obtain the structure in which injection can be quickly performed on the opposite polarity charges.

The first blocking layer 102 and the second blocking layer 104 are configured such that the photoelectric conversion unit 10 have diode characteristics. That is, when the first blocking layer 102 is formed of a P-type semiconductor, the second blocking layer 104 is formed of an N-type semiconductor. In this case, signal charges are electrons.

The second electrode 105 is formed of a conductive member such as a metal. For the second electrode 105, the same material as the conductive member forming a wiring or the conductive member forming a pad electrode used for connection to the outside may be used. For example, a material such as Al, Cu, TiN, or the like may be used as appropriate. With such a configuration, it is possible to form the second electrode 105 and the conductive material forming a wiring or a pad electrode at the same time. Therefore, a manufacturing process can be simplified.

Operation of Photoelectric Conversion Device

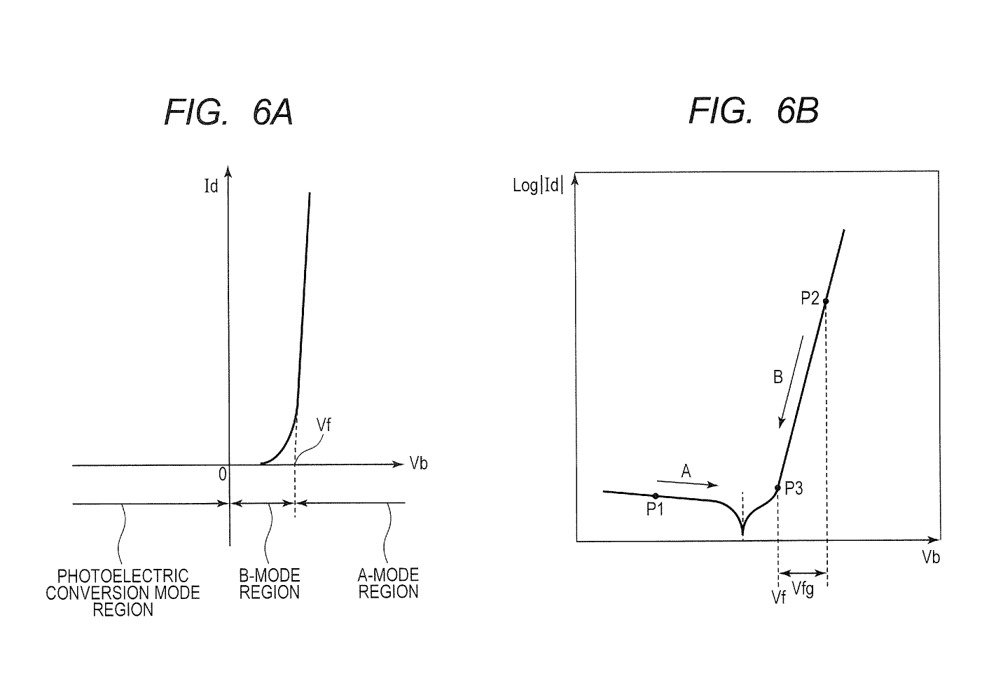

FIG. 6A and FIG. 6B illustrate the I-V characteristics of a diode of the photoelectric conversion unit 10. FIG. 6B is a rewritten version of the I-V characteristics of FIG. 6A with a logarithmic vertical axis of the absolute value of a current Id. In FIG. 6A, the vertical axis represents the current Id when it is dark, and the horizontal axis represents a bias voltage Vb applied to the photoelectric conversion unit 10. The voltage Vf is a forward rising voltage. When a reverse bias voltage of the diode is applied to the photoelectric conversion unit 10, the photoelectric conversion unit 10 performs photoelectric conversion (photoelectric conversion mode). In the photoelectric conversion mode, accumulation of signal charges is also performed. In an A-mode region of a forward bias condition, the photoelectric conversion unit 10 performs an A-mode film reset (hereafter, simply referred to as “reset”) and performs reset of the node B that is a floating gate electrode. Here, the A-mode region is an operation region of the photoelectric conversion unit 10 when a forward bias voltage higher than the rising voltage Vf is applied. In a B-mode region of a voltage from 0 to Vf, the photoelectric conversion unit 10 performs a global shutter operation described later. In the present embodiment, reset can be performed by utilizing the photoelectric conversion unit 10 for photoelectric conversion and causing the photoelectric conversion unit 10 to operate as a diode switch.

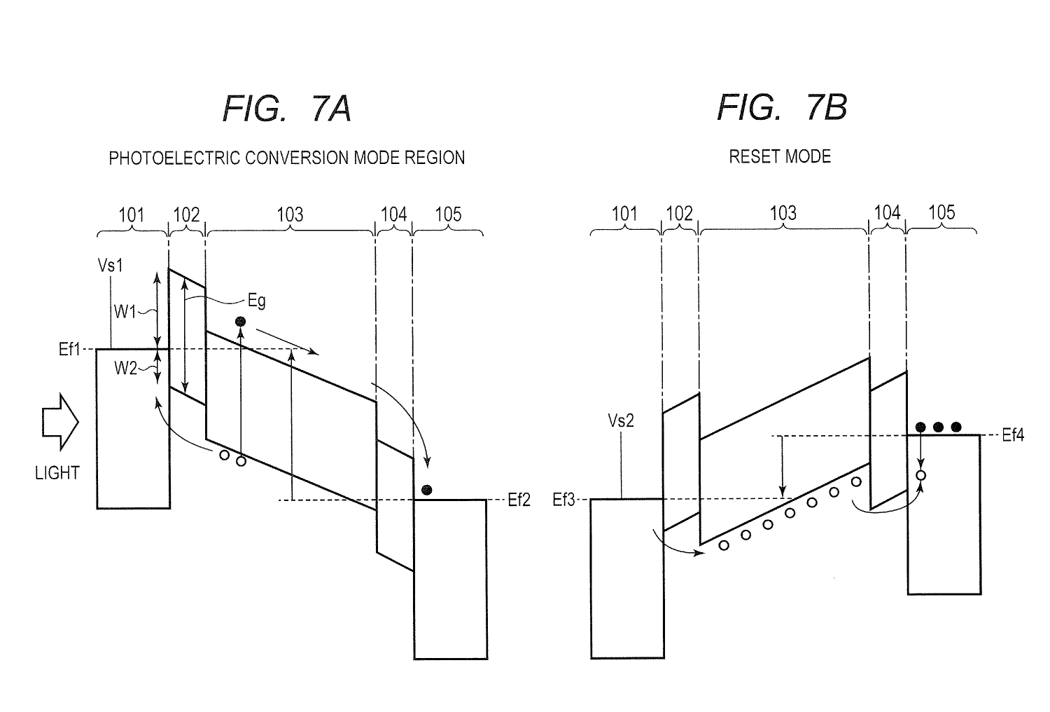

FIG. 7A and FIG. 7B schematically illustrate a potential in the photoelectric conversion unit 10. FIG. 7A and FIG. 7B illustrate the energy bands of the first electrode 101, the first blocking layer 102, the photoelectric conversion layer 103, the second blocking layer 104, and the second electrode 105. The vertical direction of the energy band illustrated in FIG. 7A and FIG. 7B represents a potential with respect to an electron, and a higher energy level indicates that the potential with respect to an electron is high. A lower energy level therefore indicates that the voltage is high. The energy level Ef1, Ef2, Ef3, and Ef4 each denote a Fermi level at each electrode. A relationship of the bandgap between a conductive band and a valence electron band is illustrated for the first blocking layer (opposite polarity charge injection portion) 102, the photoelectric conversion layer 103, and the second blocking layer 104. With this configuration, the photoelectric conversion unit 10 forms a diode. For electrons that are signal charges, it is desirable for the photoelectric conversion layer 103 to be depleted and, preferably, to be completely depleted. When depletion is insufficient, a dark current (electrons and halls) may be present inside the photoelectric conversion layer 103, and a dark signal due to recoupling of dark charges may increase during photoelectric conversion. Thus, in the photoelectric conversion mode, good photoelectric conversion characteristics can be realized by depletion of the photoelectric conversion unit. The first blocking layer 102 prevents (blocks) electrons from being injected from the first electrode 101 to the photoelectric conversion layer 103. Further, the second blocking layer 104 prevents (blocks) halls from being injected from the second electrode 105 to the photoelectric conversion layer 103.

The energy band of FIG. 7A corresponds to a photoelectric conversion (signal charge accumulation) mode in FIG. 6A and illustrates a state where the photoelectric conversion unit 10 performs photoelectric conversion and accumulates signal charges in the second electrode 105. Each electron and each hall generated by photoelectric conversion are represented by a black circle and a white circle, respectively. In the present embodiment, signal charges are electrons. A bias voltage Vs1 (for example, 0 V) is applied to the first electrode 101 made of ITO such that the photoelectric conversion unit 10 operates in the photoelectric conversion mode region. The photoelectric conversion layer 103 becomes a depletion state and starts accumulation of signal charges (the operation point P1 of FIG. 6B). At this time, electrons of the carrier generated by the photoelectric conversion layer 103 drift to the second electrode 105 by the bias voltage Vb and are accumulated as signal charges for a desired accumulation period. This causes the potential of the node B to decrease. The photoelectric conversion unit 10 is in a reverse bias state, and electrons are not injected from the first electrode 101 to the photoelectric conversion layer 103 due to the first blocking layer 102. As signal accumulation proceeds, the photoelectric conversion layer 103 changes toward a flat band state and the operation point moves in a direction denoted by the arrow A in FIG. 6B. In a saturated state, the operation point moves to a flat band state, that is, to a state where the bias voltage Vb becomes 0 V. On the other hand, halls generated in the photoelectric conversion layer 103 drift toward the first electrode 101 due to the bias voltage Vb and are drained outside the photoelectric conversion unit 10. Thus, halls do not contribute to a pixel signal in the present embodiment.

The energy band of FIG. 7B corresponds to the A-mode region in FIG. 6A and illustrates a state of resetting signal charges accumulated in the second electrode via the photoelectric conversion unit 10. A bias voltage Vs2 is applied to the first electrode 101 such that the photoelectric conversion unit 10 operates in the A-mode region. The photoelectric conversion unit 10 starts reset of signal charges (the operation point P2 of FIG. 6B). At this time, as illustrated in FIG. 7B, a forward bias voltage that is greater or equal to the rising voltage Vf is applied to the photoelectric conversion unit 10, and a large number of halls are injected from the first electrode 101 to the photoelectric conversion layer 103. The halls quickly drift to the second electrode 105 by the bias voltage Vb and are recombined with electrons of signal charges accumulated in the second electrode 105, and thereby the second electrode 105 is reset to a desired potential. Reset of the second electrode 105 causes the floating gate electrode, that is, the node B to be reset. At this time, Equation (1) is established, where the reset voltage of the node B is denoted as Vfg.

Vb=Vs2−Vfg≥Vf (1)

For example, when signal accumulation is performed until the photoelectric conversion layer 103 reaches a saturated state in the photoelectric conversion mode of FIG. 7A, the photoelectric conversion layer 103 changes to be in a flat band. The voltage of the node B at this time is assumed to be 1 V, and the forward rising voltage Vf of the photoelectric conversion unit 10 is assumed to be 0.5 V. The bias voltage Vs2 at the start of reset is assumed to be 3.5 V and, when reset of the floating gate electrode is performed from a saturated state, the bias voltage Vb is represented by Equation (2).

Vb=3.5V−Vfg≥0.5V (2)

In FIG. 6B, once a reset operation is started from the operation point P2 and the potential of the node B starts increasing, the bias voltage Vb decreases. Thereby, according to Equation (2), a current due to injected halls starts decreasing, and the operation point of the photoelectric conversion unit 10 moves in a direction illustrated by the arrow B of FIG. 6B. When the reset voltage Vfg of the node B becomes 3 V, this causes the bias voltage Vb to be equal to the rising voltage Vf, and therefore little current flows and the reset operation ends. At this time, the node B is set to 3 V as the reset voltage Vfg.

It is then possible to cause the photoelectric conversion unit 10 to enter the photoelectric conversion (signal charge accumulation) mode by again applying the bias voltage Vs1 to the first electrode 101.

In the present embodiment, by utilizing the forward diode characteristics of the photoelectric conversion unit 10 for resetting the node B, halls that are charges with a polarity opposite to electrons, which are signal charges, are quickly injected to the photoelectric conversion layer 103. By recoupling halls to signal charges in the second electrode 105, fast reset can be performed.

Note that, when halls are used in the signal charges, the same advantage can be realized by injecting electrons to cause recoupling to halls. Further, even when a light enters the photoelectric conversion unit 10 during a reset operation, the reset operation is not prevented. In this case, in the reset mode of FIG. 7B, since electrons generated by a light are drained to the first electrode 101 and halls drift to the second electrode 105, an effect of assisting a reset operation (optical assist effect) can be obtained.

In FIG. 7A and FIG. 7B, the first blocking layer 102, the photoelectric conversion layer 103, and the second blocking layer 104 are formed of the homogeneous semiconductor material and thus form homojunction. In order to realize diode characteristics in the homojunction, the impurity concentration of the photoelectric conversion layer 103 and the impurity concentration of the first blocking layer 102 and the second blocking layer 104 are different from each other. For example, the first blocking layer 102 is formed of a P-type semiconductor material, the photoelectric conversion layer 3 is formed of an intrinsic semiconductor, and the second blocking layer 104 is formed of an N-type semiconductor material. In FIG. 7A and FIG. 7B, between the first electrode 101 and the first blocking layer 102, an energy barrier to signal charges is denoted as W1 and an energy barrier to halls of signal charges is denoted as W2. Further, in the present embodiment, it is desirable to form the photoelectric conversion unit 10 so as to satisfy the following Equations (3) to (5), where the bandgap of the first blocking layer 102 is denoted as Eg.

Eg=W1+W2 (3)

0≤W2<W1 (4)

W1>Eg/2 (5)

An increase in the energy barrier W1 can prevent (block) signal charges from being injected from the first electrode 101 in the photoelectric conversion mode. Since a general photoelectric conversion film is used only for photoelectric conversion, it is sufficient to design the band structure by taking the energy barrier W1 into consideration. On the other hand, the photoelectric conversion film in the present embodiment performs reset of signal charges by utilizing forward characteristics of a diode. In this case, the energy barrier W2 is required to be reduced to quickly inject opposite polarity charges of signal charges from the first electrode 101 to the photoelectric conversion layer 103. Thus, when electrons are utilized as signal charges, it is preferable to utilize a low concentration P-type semiconductor as the photoelectric conversion layer 103.

In FIG. 4 of the conventional art (Japanese Patent Application Laid-Open No. 2011-187544), the above-described Equations (3) to (5) are not satisfied when reset is performed between the common electrode and the photoelectric conversion layer. In the conventional art, halls that are opposite polarity charges of signal charges are not injected from the first electrode to the photoelectric conversion layer as seen in the present embodiment, and thus the reset operation according to the principle of the present embodiment cannot be performed. The conventional art merely performs a reset operation by draining charges accumulated in a pixel electrode (second electrode) to the common electrode side via the photoelectric conversion layer, but does not perform the reset operation based on the principle of the present embodiment. Therefore, in the conventional art, a fast reset operation cannot be performed.

### Modified Examples

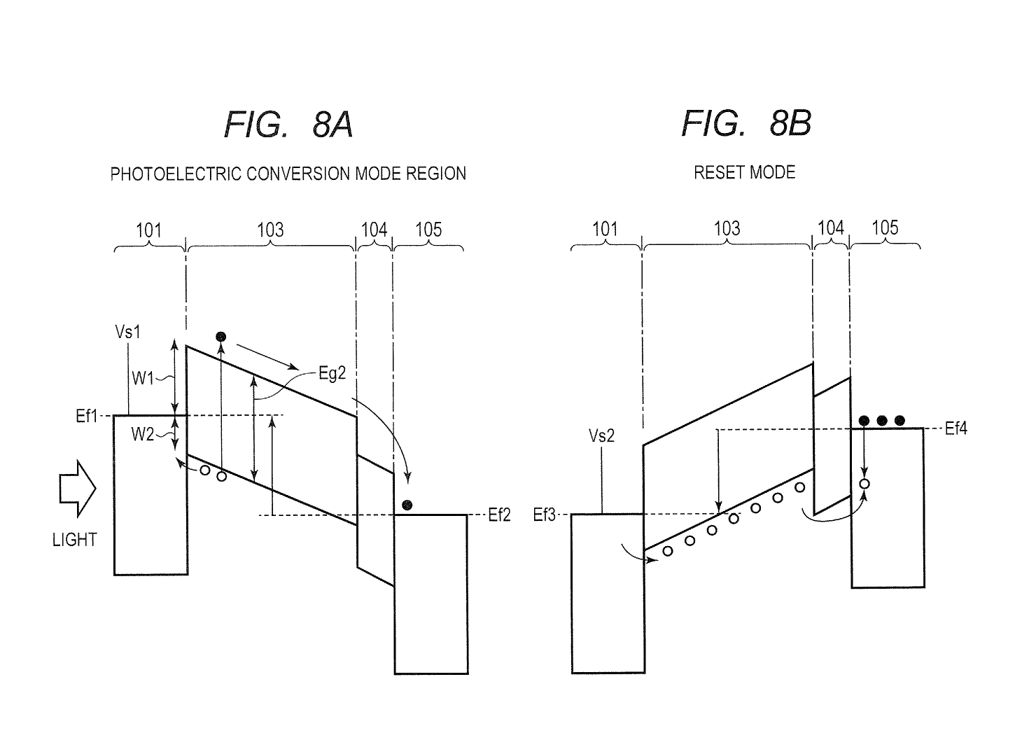

FIG. 8A and FIG. 8B schematically illustrate the potential in a modified example of the photoelectric conversion unit 10 in the present embodiment. In this modified example, no first blocking layer (charge injection portion) 102 is provided. Instead, the function of the first blocking layer 102 is realized by using a Schottky barrier of the first electrode 101 and the photoelectric conversion layer 103. In FIG. 8A and FIG. 8B, the above-described Equations (3) to (5) are satisfied among the energy barrier W1 for signal charges formed between the first electrode 101 and the photoelectric conversion layer 103, the energy barrier W2 for halls to signal charges, and the bandgap Eg2 of the photoelectric conversion layer 103. In the photoelectric conversion mode, no electron is injected from the first electrode 101 to the photoelectric conversion layer 103 due to the energy barrier W1. On the other hand, in the signal charge reset mode, halls that are opposite polarity charges of signal charges are quickly injected from the first electrode 101 to the photoelectric conversion layer 103. The halls are quickly recombined with electrons that are signal charges accumulated in the second electrode 105, and reset is performed.

Drive Method of Photoelectric Conversion Device

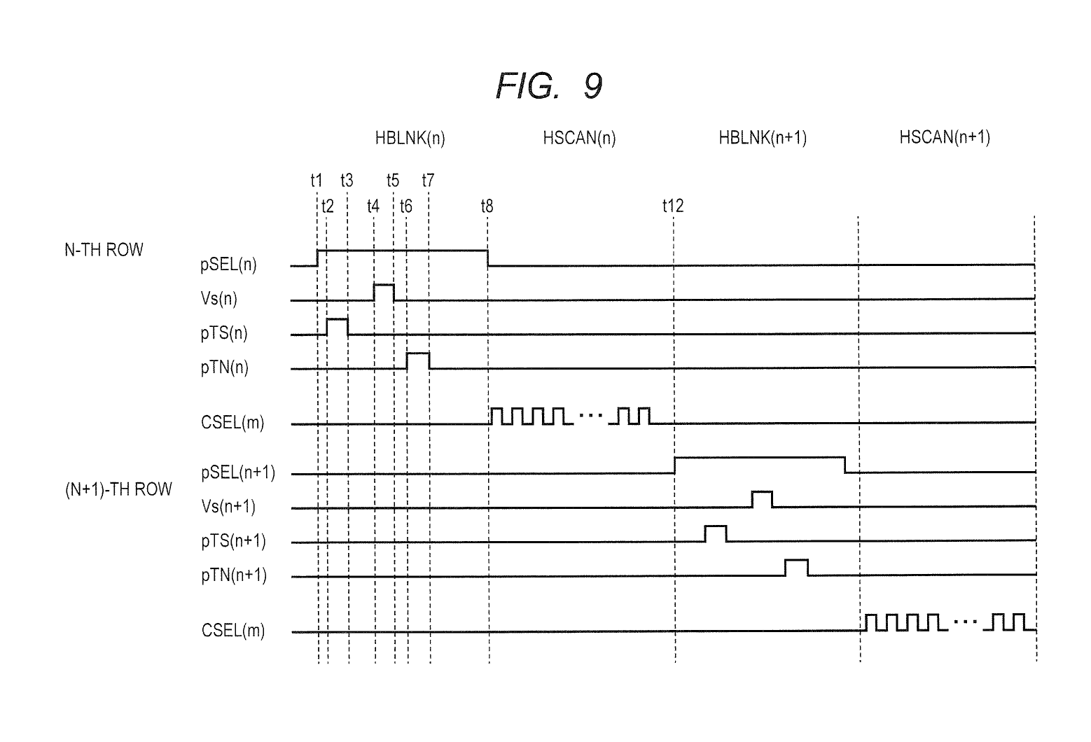

Next, a drive method of the photoelectric conversion device according to the present embodiment will be described. FIG. 9 illustrates a timing chart of drive signals used for the photoelectric conversion device of the present embodiment. FIG. 9 illustrates drive signals corresponding to readout operations of signals for two rows of the n-th row and the (n+1)-th row.

When each of a drive signal pSEL, a drive signal pTN, and a drive signal pTS is a high level, the corresponding transistor or switch is turned on. When each of the drive signal pSEL, the drive signal pTN, and the drive signal pTS is a low level, the corresponding transistor or switch is turned off. The bias voltage Vs includes the bias voltage Vs1 and the bias voltage Vs2. The drive signal pSEL, the drive signal pTN, the drive signal pTS, and the bias voltage Vs are supplied by the row drive circuit 2.

In the drive of the photoelectric conversion device of the present embodiment, a so-called rolling shutter operation is performed. Before the time t1, the photoelectric conversion unit 10 of the pixel 1 on the n-th row and the photoelectric conversion unit 10 of the pixel 1 on the (n+1)-th row are in a state of accumulating signal charges. Further, before the time t1, both the bias voltage Vs(n) on the n-th row and the bias voltage Vs(n+1) on the (n+1)-th row are the bias voltage Vs1.

At the time t1, the drive signal pSEL(n) becomes a high level, and the selection transistor 12 of the pixel 1 on the n-th row is turned on. Thereby, the pixel signal S including an optical signal accumulated in the node B and a noise signal due to the threshold variation of the amplification transistor 11 is output from the amplification transistor 11 of the pixel 1 on the n-th row to the column signal line 15.

At the time t2, the drive signal pTS(n) becomes a high level, and a pixel signal S amplified by the amplifier 301 is output to the capacitor CTS1. At the time t3, after the drive signal pTS(n) becomes a low level, the pixel signal S is held in the capacitor CTS1.

At the time t4, the bias voltage Vs(n) transitions from the bias voltage Vs1 to the bias voltage Vs2. FIG. 7B illustrates a state of the energy band of the photoelectric conversion unit 10 at this time. Subsequently, at the time t5, the bias voltage Vs(n) transitions from the bias voltage Vs2 to the bias voltage Vs1. FIG. 7A illustrates a state of the energy band of the photoelectric conversion unit 10 at this time. From the time t4 to the time t5, signal charges of the node B are reset as described above, and the photoelectric conversion unit 10 enters the photoelectric conversion mode. At this time, the amplification transistor 11 outputs a pixel signal N including a noise due to the threshold variation to the column signal line 15 via the selection transistor 12.

At the time t6, the drive signal pTN(n) becomes a high level, and the pixel signal N is output to the capacitor CTN1. At the time t7, the drive signal pTN(n) becomes a low level, and the pixel signal N is held in the capacitor CTN1. When a light enters the photoelectric conversion unit 10 in a state where the photoelectric conversion unit 10 is in the photoelectric conversion mode, generation of charges is started due to the light, therefore a shorter interval between the time t5 and the time t6 is desirable. Note that, in a state where the bias voltage Vs(n) is set to the bias voltage Vs2 and the node B is reset (the time t4 to the time t5), the pixel signal N may be held in the capacitor CTN1.

Then, the pixel 1 on the n-th row starts accumulation of signal charges of the next frame. FIG. 7A illustrates a state of the energy band of the photoelectric conversion unit 10 during accumulation of signal charges.

At the time t8, the drive signal pSEL(n) becomes a low level and the selection transistor 12 is turned off, and thereby readout of a pixel signal from the pixel 1 on the n-th row to the column circuit 3 ends. Subsequently, from the time t8 to t12 (period HSCAN(n)), the drive signals CSEL(m) of respective columns sequentially become a high level, the pixel signals S are output from the capacitor CTS1 to the horizontal output line 311, and the pixel signals N are output from the capacitor CTN1 to the horizontal output line 313.

That is, the pixel signals N and the pixel signals S read out to the column circuit 3 are output to the output circuit 5 on a column basis. The output circuit 5 outputs the difference between the pixel signal S and the pixel signal N to the analog-to-digital conversion circuit 6. Thereby, the pixel signal S in which a noise due to a threshold variation or the like is removed can be obtained.

At the time t12, the drive signal pSEL(n+1) becomes a high level, and the selection transistor 12 of the pixel 1 on the (n+1)-th row is turned on. Subsequently, readout of pixel signals from the pixels 1 on the (n+1)-the row is performed in a period HBLNK(n+1), and pixel signals of respective columns are sequentially output in a period HSCAN(n+1).

According to the present embodiment, by utilizing forward characteristics of a diode of the photoelectric conversion device, a large number of opposite polarity charges can be injected to perform fast reset of signal charges. Further, since no reset transistor is required to be provided, an influence of kTC noise due to a reset transistor can be avoided. Furthermore, since it is not necessary to accumulate signal charges in a substrate, a dark current from the substrate can be suppressed. That is, according to the present embodiment, it is possible to realize fast reset while reducing a noise.

### Second Embodiment

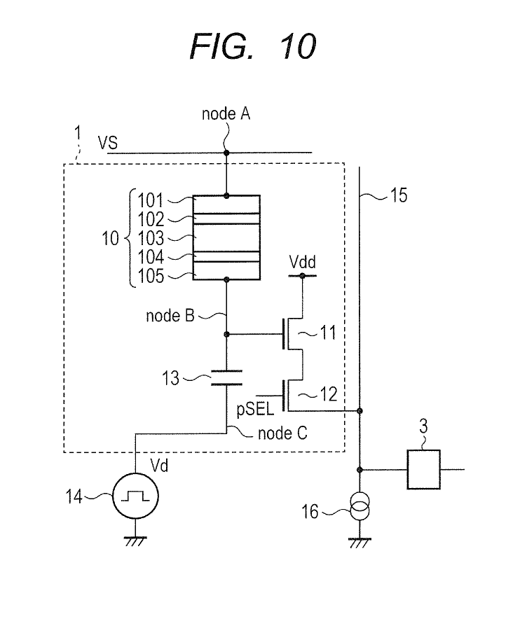

A second embodiment of the present invention will be described. FIG. 10 schematically illustrates the configuration of a pixel of a photoelectric conversion device of the present embodiment. The portions having the same function as those of FIG. 1A are labeled with the same reference. A difference of the photoelectric conversion device in the present embodiment from the first embodiment is in the node at which the voltage control circuit controls a voltage. Portions different from those of the first embodiment will be mainly described below, and the description of the same portions as those in the first embodiment will be omitted.

The pixel 1 includes the photoelectric conversion unit 10, the amplification transistor 11, the selection transistor 12, and a capacitor 13. In the present embodiment, the first electrode 101 of the photoelectric conversion unit 10 is connected to the power source VS. The power source VS supplies the bias voltage Vs to the first electrode 101.

A first terminal of the capacitor 13 is connected to the node B, and a second terminal of the capacitor 13 is connected to a node C. The second terminal of the capacitor 13 is connected to the node C, and the voltage Vd from the voltage control unit 14 is supplied to the node C. Since other configurations of the pixel 1 and the configuration of the photoelectric conversion unit 10 are the same as those of the first embodiment, the description thereof will be omitted.

In the present embodiment, the voltage control unit 14 controls the voltage Vd applied to the second terminal of the capacitor 13. The photoelectric conversion mode of the photoelectric conversion unit 10 and the reset mode of signal charges are controlled by controlling the voltage Vd.

The voltage of the node B coupling to the node C via the capacitor 13 is controlled by controlling the voltage Vd of the node C.

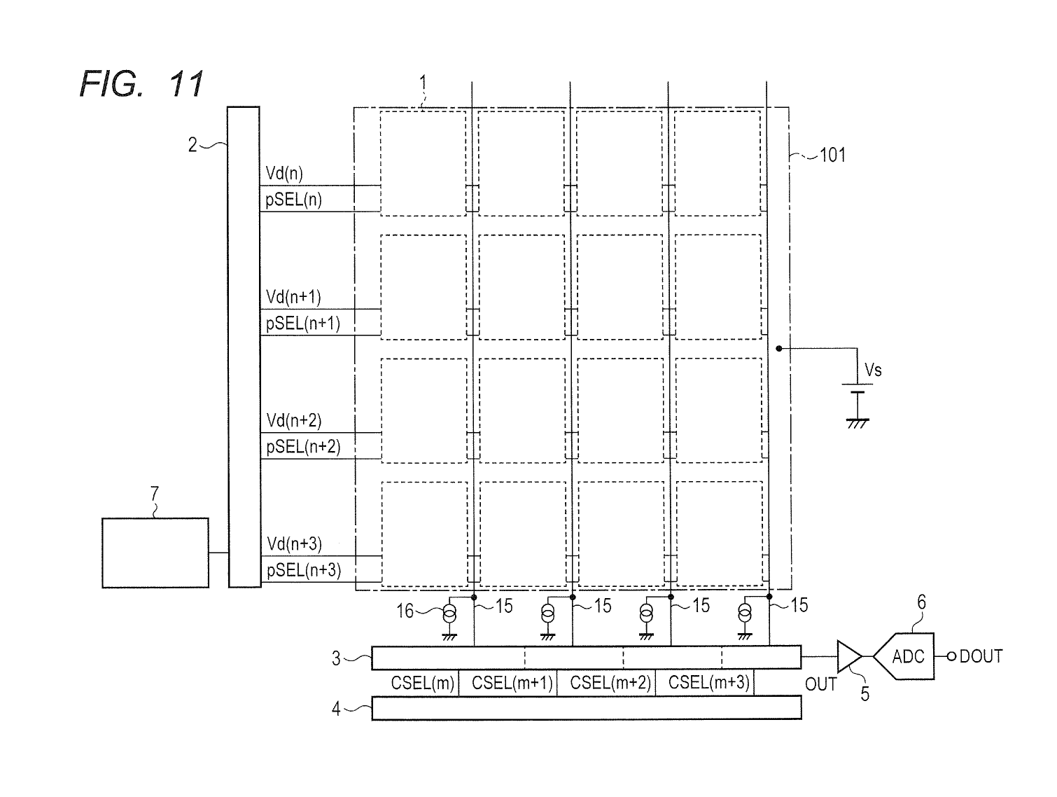

FIG. 11 is a circuit block diagram schematically illustrating the photoelectric conversion device of the present embodiment. The portions having the same function as those in FIG. 2 are labeled with the same reference.

FIG. 11 schematically illustrates the planer structure of the first electrode 101 of the photoelectric conversion unit 10. The first electrode 101 is included in the node A of FIG. 10. As illustrated in FIG. 11, the photoelectric conversion units 10 of the plurality of pixels 1 included in a plurality of rows and a plurality of columns are formed including the common first electrode 101. The bias voltage Vs is supplied to the first electrode 101. The row drive circuit 2 supplies the voltage Vd(n) and the drive signal pSEL(n) to the pixel 1 on the n-th row. The voltages Vd are supplied to the second terminals of the capacitors 13 (node C) and controlled separately on a row basis. That is, the row drive circuit 2 selects a row to supply the voltage Vd from the voltage control unit 7. Further, the drive signal pSEL(n) is supplied to the gate of the selection transistor 12 in the pixels 1 on the selected row. With such a configuration, it is possible to drive the plurality of pixels 1 on a row basis.

The column circuit 3, the column drive circuit 4, the output circuit 5, and the analog-to-digital conversion circuit 6 of the present embodiment are configured in the same manner as those in the first embodiment.

Next, the planer structure and the sectional structure of the photoelectric conversion device of the present embodiment will be described.

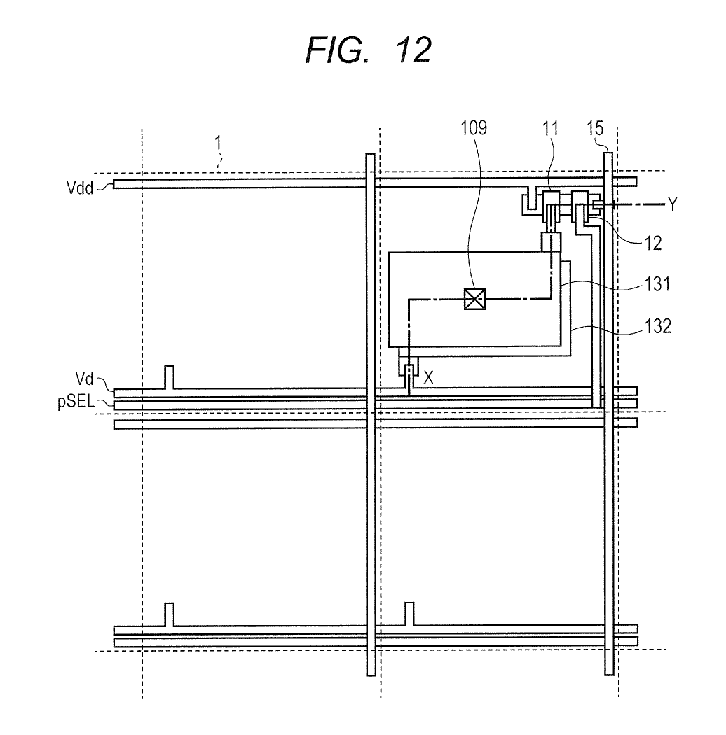

FIG. 12 schematically illustrates the planer structure of four pixels 1 arranged in a matrix of two rows by two columns. While the planer structure is illustrated for one of the four pixels 1, other pixels have the same structure.

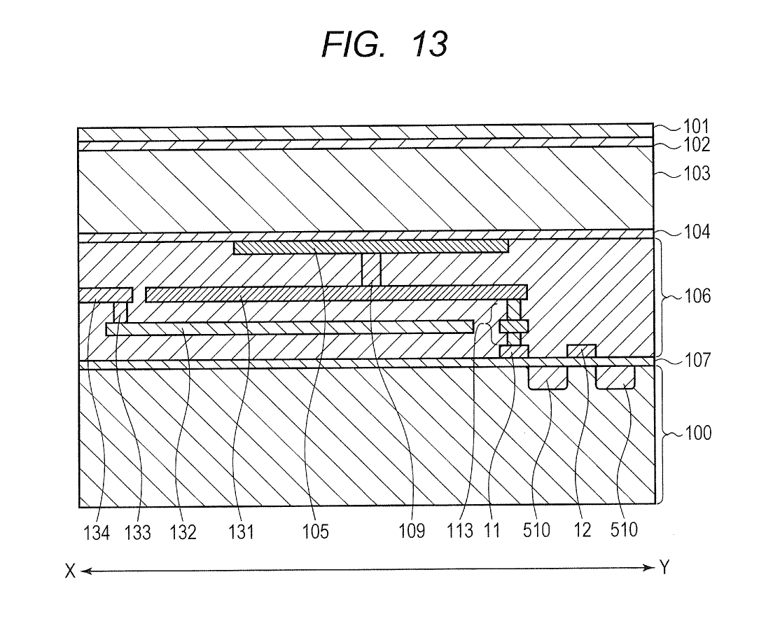

FIG. 13 schematically illustrates the sectional structure of the photoelectric conversion device taken along an X-Y dashed line in FIG. 12. Note that the same portions as that in FIG. 4 and FIG. 5 are labeled with the same references.

The capacitor 13 has an upper electrode 131 and a lower electrode 132 arranged to be face each other and is formed in the wring layer 106. The lower electrode 132 is connected to a conductive member 134 via a contact plug 133. The conductive member 134 forms a wiring that supplies the voltage Vd from the voltage control unit 14. In the present embodiment, the conductive members 134 are arranged on a row basis and electrically insulated from the conductive members 134 of other rows. With such a configuration, the voltages Vd of the second terminals of the capacitors 13 (nodes C) can be controlled separately on a row basis. Other configurations are the same as those in the first embodiment, the description thereof will be omitted.

The control method of the photoelectric conversion device in the present embodiment is basically the same as that in the first embodiment. The bias voltage Vs is fixed to 0 V, the voltage Vd is set to a voltage Vd1 (5 V) in the photoelectric conversion mode, and the voltage Vd is set to a voltage Vd2 (−2 V) in the signal charge reset mode. The row drive circuit 2 sets the voltage Vd to the voltage Vd1 (5 V) in the photoelectric conversion mode. In this case, the photoelectric conversion unit 10 can be regarded as a capacitor element in the photoelectric conversion mode. When the capacitance C1 of the photoelectric conversion unit 10 and the capacitance C2 of the capacitor 13 are the same, 2.5 V that is resulted by capacitance division is applied to the node B. As a light is irradiated thereon and electrons of signal charges are accumulated in the node B, the potential of the node B decreases. Further, the row drive circuit 2 sets the voltage Vd to the voltage Vd2 (−2 V) in the signal charge reset mode. In this case, because carriers have been injected to the photoelectric conversion unit 10, the node B is set to −2 V. As halls are injected from the first electrode 101, the halls are recombined with electrons of accumulated signal charges, and the node B is reset.

In the present embodiment, by utilizing forward characteristics of a diode of the photoelectric conversion device, a large number of opposite polarity charges of signal charges can be injected to perform fast reset of the signal charges. It is possible to perform a fast rest operation while suppressing a kTC noise and a dark current from a substrate.

### Third Embodiment

A third embodiment of the present invention will be described. In the present embodiment, the photoelectric conversion unit 10 is operated in the B-mode region illustrated in FIG. 6A during photoelectric conversion to realize global shutter (global electronic shutter). Since the pixel 1 including the photoelectric conversion unit 10 and the configuration of the photoelectric conversion device are the same as the first embodiment, the description thereof will be omitted.

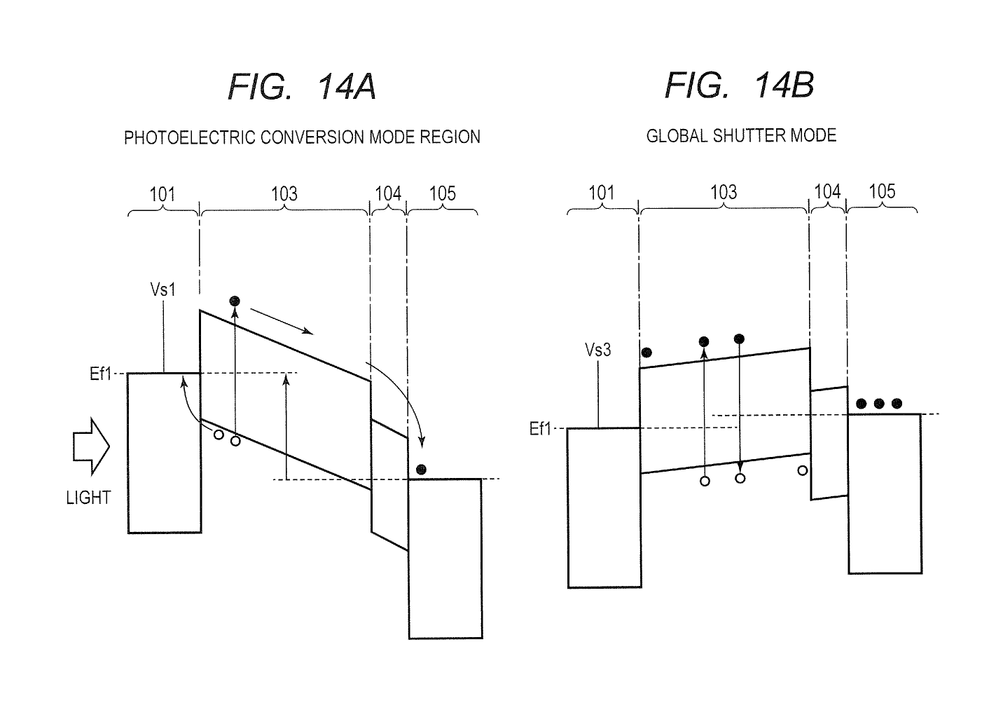

FIG. 14A and FIG. 14B schematically illustrate the potential in the photoelectric conversion unit 10 in the present embodiment. FIG. 14A illustrates the photoelectric conversion mode in a similar manner to FIG. 8A. FIG. 14B corresponds to a case where the bias of the B-mode region of FIG. 6A is applied and illustrates a global shutter mode. In this bias condition, there is little injection of halls from the first electrode 101, and the bias applied to the photoelectric conversion layer 103 is small. Therefore, injected halls neither are recombined with signal charges accumulated in the second electrode 105 (node B) nor are reset. Further, electrons of signal charges generated by a light by the photoelectric conversion layer 103 are not accumulated in the second electrode 105. That is, by performing film reset in the B-mode region, signal charges of the second electrode 105 can be held during light irradiation. By performing the operation of the present embodiment, it is possible to perform concurrent start of signal accumulation (global reset) and concurrent end of signal accumulation (global shutter) for all the pixels and thus realize global electronic shutter. Note that, when the pixel 1 of FIG. 1A is used, accumulation of signal charges due to photoelectric conversion to the node B is restricted during signal readout of the node B.

Also in the present embodiment, by utilizing forward characteristics of a diode of the photoelectric conversion device, it is possible to perform fast reset of signal charges. Further, a global electronic shutter function can be realized.

### Fourth Embodiment

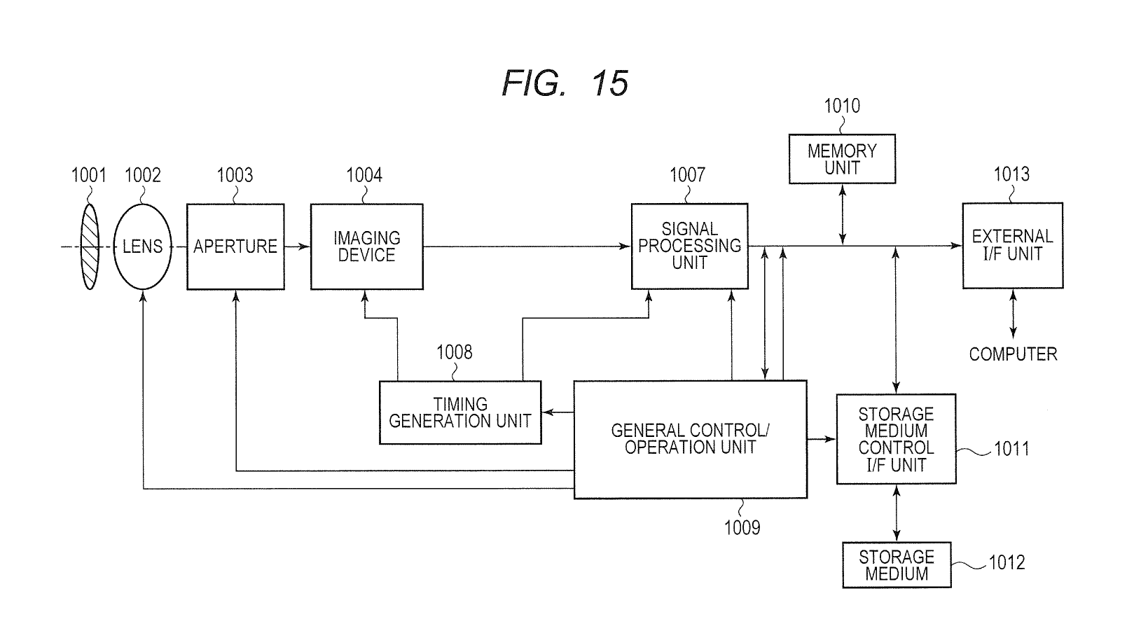

The photoelectric conversion devices in the embodiments described above can be applied to various imaging systems. The imaging system may be a digital still camera, a digital camcorder, a camera head, a copier machine, a fax machine, a mobile phone, an on-vehicle camera, an observation satellite, a surveillance camera, or the like. FIG. 15 illustrates a block diagram of a digital still camera as an example of the imaging system.

The imaging system illustrated in FIG. 15 includes a barrier 1001, a lens 1002, an aperture 1003, an imaging device (photoelectric conversion device) 1004, a signal processing unit 1007, a timing generation unit 1008, a general control/operation unit 1009, a memory unit 1010, a storage medium control I/F unit 1011, a storage medium 1012, and an external I/F unit 1013. The barrier 1001 protects a lens 1002, and the lens 1002 captures an optical image of a subject on the imaging device 1004. The aperture 1003 changes a light amount passing through the lens 1002. The imaging device 1004 has the photoelectric conversion device described in the above embodiments and converts an optical image captured by the lens 1002 into image data. Here, an AD conversion unit is formed on a semiconductor substrate of the imaging device 1004. The signal processing unit 1007 performs various correction or compression on image pickup data output from the imaging device 1004. The timing generation unit 1008 outputs various timing signals to the imaging device 1004 and the signal processing unit 1007. The general control/operation unit 1009 controls the entire digital still camera, and the memory unit 1010 temporarily stores image data. The storage medium control I/F unit 1011 is an interface for performing storage or readout of image data to the storage medium 1012, and the storage medium 1012 is a removable storage medium such as a semiconductor memory for performing storage or readout of image pickup data. The external I/F unit 1013 is an interface for communicating with an external computer or the like. The timing signal or the like may be input from the outside of the imaging system, and the imaging system may be any imaging system that has at least the imaging device 1004 and the signal processing unit 1007 for processing an image pickup signal output from the imaging device 1004.

In the present embodiment, the configuration in which the imaging device 1004 and the AD conversion unit are provided on separate semiconductor substrates has been described. However, the imaging device 1004 and the AD conversion unit may be formed on the same semiconductor substrate. Further, the imaging device 1004 and the signal processing unit 1007 may be formed on the same semiconductor substrate.

Further, each of the pixels may have the first photoelectric conversion unit and a second photoelectric conversion unit. The signal processing unit 1007 may be configured to process a pixel signal based on charges generated in the first photoelectric conversion unit and a pixel signal based on charges generated in the second photoelectric conversion unit to acquire distance information on the distance from the imaging device 1004 to a subject.

In the embodiment of the imaging system, any of the photoelectric conversion devices of the embodiments described above is used for the imaging device 1004. According to such a configuration, an image with a reduced noise can be acquired without using a reset transistor.

### Fifth Embodiment

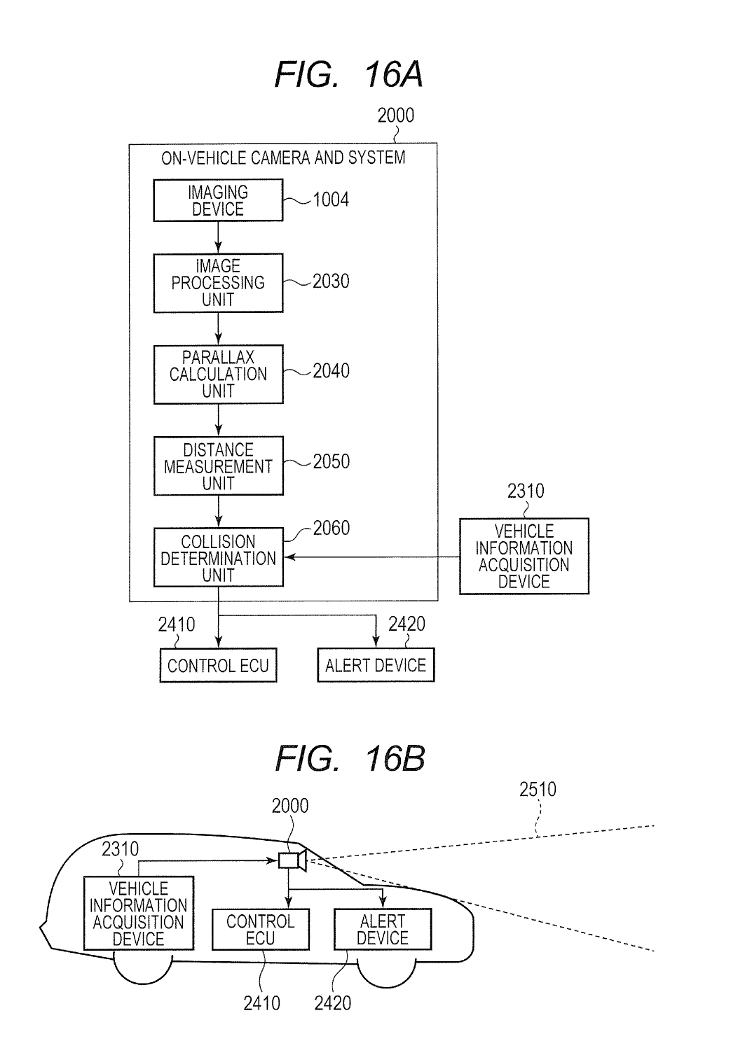

FIG. 16A and FIG. 16B illustrate an example of the imaging system related to an on-vehicle camera in a fifth embodiment of the present invention. The imaging system 2000 has the imaging device (photoelectric conversion device) 1004 of the above-described embodiments. The imaging system 2000 has an image processing unit 2030 that performs image processing on a plurality of image data acquired by the imaging device 1004 and a parallax calculation unit 2040 that calculates a parallax (a phase difference of parallax images) from the plurality of image data acquired by the imaging system 2000. Further, the imaging system 2000 has a distance measurement unit 2050 that calculates a distance to the object based on the calculated parallax and a collision determination unit 2060 that determines whether or not there is a collision possibility based on the calculated distance. Here, the parallax calculation unit 2040 and the distance measurement unit 2050 are an example of a distance information acquisition unit that acquires distance information to the object. That is, the distance information is information regarding a parallax, a defocus amount, a distance to an object, or the like. The collision determination unit 2060 may use any of the distance information to determine the collision possibility. The distance information acquisition unit may be implemented by dedicatedly designed hardware or may be implemented by a software module. Further, the distance information acquisition unit may be implemented by a Field Programmable Gate Array (FPGA) or an Application Specific Integrated Circuit (ASIC), or may be implemented by combination thereof.

The imaging system 2000 is connected to the vehicle information acquisition device 2310 and can acquire vehicle information such as a vehicle speed, a yaw rate, a steering angle, or the like. Further, the imaging system 2000 is connected with a control ECU 2410, which is a control device that outputs a control signal for causing a vehicle to generate braking force based on a determination result by the collision determination unit 2060. Further, the imaging system 2000 is connected with an alert device 2420 that issues an alert to the driver based on a determination result by the collision determination unit 2060. For example, when the collision possibility is high as the determination result of the collision determination unit 2060, the control ECU 2410 performs vehicle control to avoid a collision or reduce damage by applying brake, pushing back an accelerator, suppressing engine power, or the like. The alert device 2420 alerts a user by sounding an alert such as a sound, displaying alert information on a display of a car navigation system or the like, providing vibration to seat belt or a steering wheel, or the like. The imaging system 2000 functions as a control unit adapted to control the operation of controlling the vehicle as described above.

In the present embodiment, the imaging system 2000 captures an image of a surrounding area such as a front area or a rear area, for example, of a vehicle. FIG. 16B illustrates the imaging system in a case of capturing a front area of a vehicle (a capturing area 2510). The vehicle information acquisition device 2310 as a capturing control unit transmits instructions to the imaging system 2000 or the imaging device 1004 to perform the operation described in the above first to third embodiments. Since the operation of the imaging device 1004 is the same as that in the first to third embodiments, the description there of will be omitted here. Such a configuration can further improve the ranging accuracy.

Although the example of control for avoiding a collision to another vehicle has been illustrated in the above description, the embodiment is applicable to automatic driving control for following another vehicle, automatic driving control for not going out of a traffic lane, or the like. Furthermore, the imaging system is not limited to a vehicle such as the subject vehicle, and can be applied to a moving unit (moving apparatus) such as a ship, an airplane, or an industrial robot, for example. In addition, the imaging system can be widely applied to a device which utilizes object recognition, such as an intelligent transportation system (ITS), without being limited to moving units.

### OTHER EMBODIMENTS

The present invention is not limited to the above-described embodiments, and various modifications are possible. For example, an example in which a part of the configuration of any of the embodiments is added to another embodiment or an example in which a part of the configuration is replaced with a part of the configuration of another embodiment may be considered to be an embodiment of the present invention.

In the embodiments described above, although the description has been provided assuming that each transistor of the pixel 1 is formed of an N-type transistor, such transistor of the pixel 1 may be formed on a P-type transistor. In this case, each drive signal level described above is inverted. Further, the circuit configuration of the pixel 1 is not limited to that illustrated in FIG. 2 but may be changed as appropriate. For example, the pixel 1 may be the dual-pixel structure having two photoelectric conversion unit in a single pixel.

Note that any of the embodiments described above has been provided to merely illustrate an example of embodiment in implementing the present invention, and the technical scope of the present invention is not to be construed in a limiting sense by these embodiments. That is, the present invention can be implemented in various forms without departing from the technical concept thereof or the primary feature thereof.

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2016-232378, filed Nov. 30, 2016, which is hereby incorporated by reference herein in its entirety.

What is claimed is:

1. A photoelectric conversion device comprising:
a first electrode;
a second electrode;
a photoelectric conversion layer arranged between the first electrode and the second electrode;
a floating gate electrode connected to the second electrode and adapted to accumulate signal charges generated in the photoelectric conversion layer;
an amplification transistor adapted to output a signal corresponding to a potential of the floating gate electrode; and
a charge injection portion arranged between the first electrode and the photoelectric conversion layer and adapted to inject opposite polarity charges of signal charges from the first electrode to the photoelectric conversion layer to reset signal charges accumulated in the floating gate electrode.

2. The photoelectric conversion device according to claim 1, wherein the charge injection portion blocks signal charges from being injected from the first electrode to the photoelectric conversion layer.

3. The photoelectric conversion device according to claim 1, wherein the first electrode, the photoelectric conversion layer, and the second electrode form a diode.

4. The photoelectric conversion device according to claim 3 further comprising a voltage control unit adapted to control a bias voltage applied to the diode to operate the diode in a photoelectric conversion mode and a reset mode,
wherein the voltage control unit
in the photoelectric conversion mode, applies a reverse bias voltage to the diode to accumulate signal charges in the floating gate electrode, and
in the reset mode, applies a forward bias voltage to the diode to inject opposite polarity charges of signal charges from the first electrode to the photoelectric conversion layer and recombine, at the floating gate electrode, the signal charges accumulated in the floating gate electrode with the injected opposite polarity charges.

5. The photoelectric conversion device according to claim 1, wherein the charge injection portion and the photoelectric conversion layer are formed of the homogenous semiconductor material.

6. The photoelectric conversion device according to claim 5, wherein an impurity concentration of the charge injection portion and an impurity concentration of the photoelectric conversion layer are different from each other.

7. The photoelectric conversion device according to claim 5,
wherein the charge injection portion has a first conduction type, and
wherein the photoelectric conversion layer has a second conduction type that is different from the first conduction type.

8. The photoelectric conversion device according to claim 1,
wherein the charge injection portion is formed of a first semiconductor material, and
wherein the photoelectric conversion layer is formed of a second semiconductor material that is different from the first semiconductor material.

9. The photoelectric conversion device according to claim 8, wherein a bandgap of the charge injection portion and a bandgap of the photoelectric conversion layer are different from each other.

10. The photoelectric conversion device according to claim 8, wherein the charge injection portion and the photoelectric conversion layer form a heterojunction.

11. The photoelectric conversion device according to claim 2, wherein an energy barrier W1 to signal charges formed between the first electrode and the charge injection portion, an energy barrier W2 to halls of signal charges, and a bandgap Eg of the charge injection portion satisfy equations:
Eg=W1+W2,
0≤W2<W1, and
W1>Eg/2.

12. A drive method of a photoelectric conversion device comprising a first electrode, a second electrode, a photoelectric conversion layer arranged between the first electrode and the second electrode, a floating gate electrode connected to the second electrode and adapted to accumulate signal charges generated in the photoelectric conversion layer, an amplification transistor adapted to output a signal corresponding to a potential of the floating gate electrode, and a charge injection portion arranged between the first electrode and the photoelectric conversion layer,
the drive method comprising:
injecting opposite polarity charges of signal charges from the first electrode to the photoelectric conversion layer to reset signal charges accumulated in the floating gate electrode.

13. An imaging system comprising:
the photoelectric conversion device according to claim 1; and
a signal processing unit adapted to process a signal from the photoelectric conversion device.

14. A moving unit comprising:
the photoelectric conversion device according to claim 1;
a distance information acquisition unit adapted to acquire, from a parallax image based on signals output from pixels of the photoelectric conversion device, distance information on a distance to a subject; and
a control unit adapted to control the moving unit based on the distance information.
